(19) United States
(12) Patent Application Publication
(10) Pub. No.: US 2006/0138548 A1
(43) Pub. Date: Jun. 29, 2006

(54) Strained silicon, gate engineered Fermi-FETs

(75) Inventors: William R. Richards JR., Cary, NC (US); Mike Yen-Chao Shen, Austin, TX (US)

Correspondence Address: MYERS BIGEL SIBLEY & SAJOVEC, PO BOX 37428, RALEIGH, NC, 27627, US

(73) Assignee: Thunderbird Technologies, Inc.

(21) Appl. No.: 11/295,105

(22) Filed: Dec. 6, 2005

Related U.S. Application Data
(60) Provisional application No. 60/634,016, filed on Dec. 7, 2004.

(51) Int. Cl. H01L 29/94

(52) U.S. Cl. 257/368

(57) ABSTRACT

A field effect transistor includes a strained silicon channel in a substrate, source/drain regions in the substrate at opposite ends of the strained silicon channel, a gate insulating layer on the strained silicon channel, and a gate on the gate insulating layer. The doping of the strained silicon channel, the doping of the substrate and/or the depth of the strained silicon channel are configured to produce nearly zero vertical electric field in the gate insulating layer and in the strained silicon channel surface at a threshold voltage of the field effect transistor. Moreover, the gate is configured to provide a gate work function that is close to a mid-bandgap of silicon. Accordingly, a Fermi-FET with a strained silicon channel and a gate layer with a mid-bandgap work function are provided. Related fabrication methods using epitaxial growth also are described.

### CROSS-REFERENCE TO RELATED APPLICATION

This application claims the benefit of provisional Application No. 60/634,016, filed Dec. 7, 2004, entitled Strained Silicon Gate Engineered Fermi-FETs, assigned to the assignee of the present invention, the disclosure of which is hereby incorporated herein by reference in its entirety as if set forth fully herein.

### FIELD OF THE INVENTION

The invention relates to semiconductor devices and fabrication methods, and more particularly to field effect transistors (FETs) and fabrication methods therefor.

### BACKGROUND OF THE INVENTION

Fermi-FET devices have been well-explored by Thunderbird Technologies, the assignee of the present invention, and others for a number of years. Fermi-FET transistors are described in the following U.S. Pat. Nos. 4,984,043; 4,990,974; 5,151,759; 5,194,923; 5,222,039; 5,367,186; 5,369,295; 5,371,396; 5,374,836; 5,438,007; 5,440,160; 5,525,822; 5,543,654; 5,698,884; 5,786,620; 5,814,869; 5,885,876; and 6,555,872, all of which are assigned to the assignee of the present invention, the disclosures of all of which are incorporated herein by reference as if set forth fully herein.

At coarser geometries, the supply voltage can be high enough to allow the use of degenerately-doped polysilicon gates for the n and p-channel Fermi-FET devices. For more deeply scaled CMOS technologies, a mid-bandgap gate material may be used to provide device threshold voltages that can be more suitable for device operation, whether for high-performance (low V_{T}) or low-power (higher V_{T}) applications. See, for example, U.S. Pat. No. 5,952,701. This is because the channel engineering of the Fermi-FET can use specific doping profiles in order to realize the low-field benefits of the device design. A device designer can balance the subthreshold behavior, including I_{OFF}, subthreshold slope S, drain-induced barrier lowering (DIBL) and V_{T} roll-off vs. the performance, including I_{DSAT} (the off vs. on-current) and capacitances given the technology constraints of the gate stack, oxide thickness tₒₓ, foundry tool sets, etc. and product requirements.

### SUMMARY OF THE INVENTION

Field effect transistors according to exemplary embodiments of the present invention include a strained silicon channel in a substrate, source/drain regions in the substrate at opposite ends of the strained silicon channel, a gate insulating layer on the strained silicon channel, and a gate on the gate insulating layer. The doping of the strained silicon channel, the doping of the substrate and/or the depth of the strained silicon channel are configured to produce nearly zero vertical electric field in the gate insulating layer and in the strained silicon channel adjacent thereto at a threshold voltage of the field effect transistor. Moreover, the gate is configured to provide a gate work function that is close to a mid-bandgap of silicon. Accordingly, a Fermi-FET with a strained silicon channel and a gate with a mid-bandgap work function may be provided.

In some embodiments, a relaxed silicon-germanium buffer layer is provided between the substrate and the strained silicon channel. The relaxed silicon-germanium buffer layer is configured to apply strain to the strained silicon channel. Moreover, in some embodiments, the gate comprises polysilicon-germanium. In other embodiments, a polysilicon layer also may be provided on the polysilicon-germanium remote from the gate insulating layer.

In some embodiments, the gate is configured to provide a gate work function that is within about 0.3 eV of the mid-bandgap of silicon. Moreover, in other embodiments, the gate is configured to provide a gate work function of about 4.7 eV.

In other embodiments, the doping of the channel, the doping of the substrate and/or the depth of the channel are selected according to

$${x}_{i} = \frac{{N}_{A}}{{N}_{D} + {N}_{A}} \sqrt{\frac{2 {ɛ}_{s}}{q} [ [ \frac{1}{{N}_{A}} + \frac{1}{{N}_{D}} ] ]} ,$$

wherein xᵢ is the depth of the channel, N_{A} is the substrate doping, N_{D} is the channel doping, εₛ is the permittivity of silicon, and q is the elementary charge.

It will be understood by those having skill in the art that embodiments of the invention have been described above as including a Fermi-FET having nearly zero vertical electric field at threshold, combined with a strained silicon channel and a mid-bandgap gate. In other embodiments, subcombinations of these elements also may be provided. Thus, in some embodiments, a Fermi-FET may be provided with a strained silicon channel and a gate that is configured to provide a gate work function that is not close to the mid-bandgap of silicon. In other embodiments, a Fermi-FET may be provided with a gate that is configured to provide a gate work function that is close to the mid-bandgap of silicon, and that includes a channel that is not strained. In still other embodiments, conventional MOSFETs that are not Fermi-FETs may be provided with a strained silicon channel and with a mid-bandgap gate.

Field effect transistors may be fabricated according to exemplary embodiments of the present invention by epitaxially growing a relaxed silicon-germanium buffer on a substrate, epitaxially growing a strained silicon channel on the relaxed silicon-germanium buffer layer, and forming source/drain regions in the substrate at opposite ends of the strained silicon channel. A gate insulating layer is formed on the strained silicon channel, and a gate that is configured to provide a gate work function that is close to a mid-bandgap of silicon is formed thereon. The doping of the strained silicon channel, the doping of the substrate and/or the depth of the strained silicon channel may be configured to produce nearly zero vertical electric field in the gate insulating layer and in the strained silicon channel adjacent thereto at a threshold voltage of the field effect transistor. In some embodiments, the source/drain regions are formed by selective epitaxial growth while epitaxially growing the relaxed silicon-germanium buffer layer and/or the strained silicon channel.

### BRIEF DESCRIPTION OF THE DRAWINGS

FIG. 1 graphically illustrates work function as a function of germanium content in silicon-germanium.

FIG. 2 graphically illustrates relative mobility enhancement for holes and electrons in silicon-germanium compared to silicon.

FIG. 3 graphically illustrates channel doping profile in the center of a channel for both conventional MOSFETs and Fermi-FET devices.

FIG. 4 graphically illustrates transverse field profiles in the center of the channel for conventional MOSFETs and Fermi-FET devices.

FIG. 5 graphically illustrates lateral profiles of transverse fields in the gate insulator (oxide) for both conventional MOSFETs and Fermi-FET devices.

FIG. 6 graphically illustrates the lateral profiles of transverse fields at the substrate surface along the device channels at the surface for both conventional MOSFETs and Fermi-FET devices.

FIG. 7 is a cross-sectional illustration of a strained silicon on silicon-germanium, silicon-germanium gate Fermi-FET according to exemplary embodiments of the present invention.

FIG. 8 is a diagram of a one-dimensional channel structure defining the doping distributions and depletion regions at the threshold voltage of the transistor of FIG. 7.

### DETAILED DESCRIPTION

### Gate Engineering

For Deep Sub-Micron (DSM) Fermi-FETs, it may be desirable to have the flexibility of setting or tuning the gate work function independent of other device characteristics. For example, the gate work function may be independent of the substrate dopings, gate oxide thickness and device geometry. With this capability, the n and p-channel gate materials could be tuned separately, allowing the n and p-channel device threshold voltages to be set independently of each other. In practice, however, this capability may be expensive, because it may use true metal gates with the capability of selectively altering the work function (for example using photolithography).

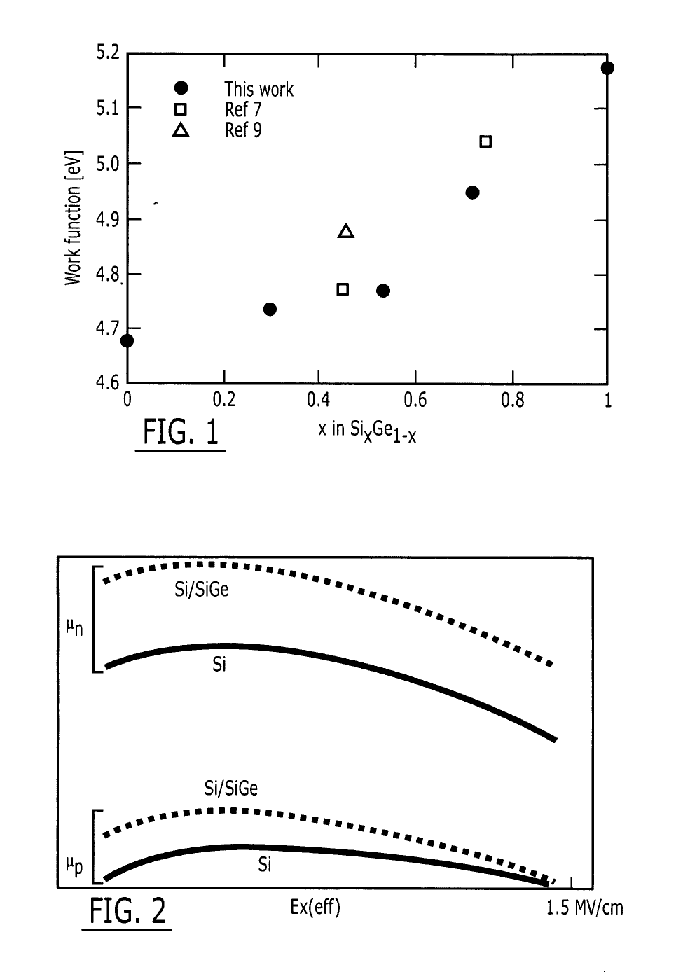

It is known to use Si₁₋ₓGeₓ gate in a conventional MOSFET, where the gate stack may be a layered arrangement of polysilicon on top of a deposited polysilicon incorporating Ge. A buffer layer of amorphous Si may also be used at the bottom of the stack, which ends up recrystallizing with the Ge content. See, for example, Hellberg et al. “Work Function of Boron-Doped Polycrystalline SiₓGe₁₋ₓ Films,” IEEE Electron Device Letters, Vol. 18, No. 9, September 1997, pp. 456-458. The Ge content causes a narrowing of the bandgap, leading to a shift in the work function. When the gate is degenerately doped p-type, work function shifts up to 400 mV have been reported in Hellberg et al. FIG. 1 is a reproduction of work function shifts as a function of the Si content as reported in Hellberg et al. Note that this figure shows work function as a function of Si, not Ge content, as is currently customary. Moreover, Ref 7 and Ref 9 in the legend refer to references from Hellberg et al. The electron affinity of the poly-Si₁₋ₓGeₓ gate is very close to the affinity of pure Si. When the gate stack is degenerately doped p-type, near the valence band edge, the shift in Fermi level due to the bandgap narrowing results in the work function shift. Practical values of Ge content can result in work functions of about 4.9 eV. Note that experimental values of work function may differ from the data shown in FIG. 1. An example gate structure could have Ge content in the poly-Si₁₋ₓGeₓ layer of 50-70% (mole fraction) and be doped with a boron dose of 10¹⁵ cm⁻³.

For Fermi-FET designs, it may be desirable to have a work function close to the midgap level of 4.72 eV, for example, due to low power supplies such as V_{DD}=1.2 V. Logic design typically uses a V_{DD}/V_{T} ratio of at least 3.5-4, meaning a V_{T} of no more than 0.3-0.4 V may be desirable. Fermi-FET designs with a true mid-bandgap work function of around 4.7 eV can provide a V_{T} of about 0.4 V. Considering only the n-channel device, a SiGe gate work function of 4.9 eV is too high, however, since the V_{T} will be around 0.6 V. Thus, a SiGe gate work function may make it difficult to design low-field Fermi-FET devices, because the resulting V_{T} values may generally be too high.

### Substrate Engineering

Relatively recently, work has taken place on the effects of lattice strain in both the substrate and gates of CMOS technology. See, Fossum et al., “Performance Projections of Scaled CMOS Devices and Circuits With Strained Si-on-SiGe Channels,” IEEE Transactions on Electron Devices, Vol. 50, No. 4, April, 2003, pp. 1042-1049, and Miyata et al., “Electron transport properties of a strained Si layer on a relaxed Si₁₋ₓGeₓ substrate by Monte Carlo simulation,” Applied Physics Letters, Vol. 62, No. 21, May, 1993, pp. 2661-2663. The application of tensile or compressive stress to the substrate of a CMOS wafer can have profound effects on the performance of the devices. The most notable effect may be that of mobility enhancement, both in the bulk and at the surface. The applied strain generally reduces the bandgap in the affected region, which can alter the effective masses of the charge carriers, and can lead to higher velocities (and mobility). In addition, the deleterious effects of phonon scattering and surface roughness may be reduced with applied strain. The literature has reported significant mobility enhancements of up to 45% for n-channel MOSFETs. See, Goo et al., “Scalability of Strained-Si nMOSFETs Down to 25 nm Gate Length,” IEEE Electron Device Letters, Vol. 24, No. 5, May, 2003, pp. 351-353.

One method to achieve the desired strain is to use an epitaxial Si/Si₁₋ₓGeₓ heterostructure, so-called bandgap engineering. A significant amount of research in this area has already taken place. Recent work has taken place devoted to understanding the physics involved and developing practical models suitable for device and circuit design, as noted in the above-cited Fossum et al. and Miyata et al. publications, and in Lim et al., “Comparison of Threshold-Voltage Shifts for Uniaxial and Biaxial Tensile-Stressed n-MOSFETs,” IEEE Electron Device Letters, Vol. 25, No. 11, November 2004, pp. 731-733; and Takagi et al., “Comparative study of phonon-limited mobility of two-dimensional electrons in strained and unstrained Si metal-oxide-semiconductor field-effect transistors,” Journal of Applied Physics, Vol. 80, No. 3, August, 1996, pp. 1567-1577. Many other techniques for straining a channel are known to those having skill in the art. From this modeling work, and experimental results reported in the literature, it has been found that the actual improvement in integrated circuit performance due to strain is generally nowhere near the improvements expected due to the measured mobility enhancement. For example, where the mobility enhancement may be known to be about 35%, the actual gain in performance, as measured by intrinsic gate delay, may be well under 20%. Moreover, the improvement in mobility may come at a price.

In particular, since the underlying physical effect is that of bandgap narrowing and band-edge shifting, several device characteristics generally are altered. The first, and possibly most significant effect, is on the mobility of the device, but there also may be a significant effect on the V_{T} of the device. The reduced bandgap and band shifting may alter the Fermi levels of the mobile carriers in the channel, leading to a reduced V_{T} for both the n and p-channel devices. This V_{T} shift can be on the order of 150-200 mV for biaxially tensile strained n-channel devices, and somewhat less for uniaxially strained devices. The reported V_{T} shifts for p-channel devices are substantially less than for the n-channel devices and are generally ignored. Until recently, little attention had been paid to understanding the reasons for the V_{T} shift. In order to compensate for the reduced V_{T}, higher dopings generally need to be used in the channel, lowering the mobility due to ionized impurity scattering and offsetting the strain-induced mobility enhancement. In addition, the higher dopings generally result in higher transverse fields.

Two other potentially detrimental effects due to the bandgap narrowing relate to the channel-to-source/drain junctions. Bandgap narrowing generally leads to increased junction leakage, which may be aggravated by the potential need for higher channel doping. In addition, the junction capacitance in the region of strain generally is increased, again aggravated by potentially higher dopings, which may reduce the dynamic performance of the device. All of these characteristics may combine to significantly degrade the benefits provided by the strain in conventional MOSFET designs.

Channel-Strained, Gate-Engineered Fermi-FETs As noted above, the use of Si₁₋ₓGeₓ gates for Fermi-FET designs may generally result in n-channel V_{T} values which are too high. It may be desirable to find a method to reduce the V_{T} of the device, apart from gate engineering. There is some latitude in the channel dopings, but for the most beneficial performance, the V_{T} range may be fairly small. If Si₁₋ₓGeₓ is applied to the Fermi-FET gate, the use of an Si_{1-y}Ge_{y} heterostructure channel may be beneficial, where y is used to differentiate the Ge content in the substrate from that used in the gate stack. After careful consideration, this indeed is the case for at least several reasons.

First is the V_{T} shift resulting from the strained channel lattice. For a given set of n-channel Fermi-FET channel conditions, the application of strain can provide a shift in the negative direction, providing just about the right magnitude for an effective mid-bandgap work function shift with a Si₁₋ₓGeₓ gate. The amount of the V_{T} shift may be dependent upon a number of factors. If a Si_{1-y}Ge_{y} heterostructure is used to provide the strained channel, the amount of Ge (y) in the relaxed buffer layer can be a key factor. It has been shown in Fossum et al., cited above that, for biaxially strained Si, the V_{T} shift can be expressed empirically as:
ΔV_{T-SiGe}=E_{g(Si)}−E_{g(SilSiGe)}=0.4y(eV)
which is expressed as the effective bandgap narrowing, with y being the fractional Ge content in the relaxed buffer. For practical Ge content values, e.g. y=0.20 at room temperature, the bandgap is reduced by about 80 meV. For higher values, which provide higher mobility, such as y=0.50, the ΔV_{T} could be around 200 mV. This is very close to the V_{T} shift that is desired for the Si₁₋ₓGeₓ gate Fermi-FET. Note that the doping levels in a Fermi-FET structure are typically much lighter than a conventional surface-channel inversion (SCI) MOSFET. Thus, using a strained Si-on-SiGe channel structure, the dopings may not need to be altered. Thus, the Fermi-FET structure could be designed as if a true mid-bandgap work function were being used for the gate, with the desired V_{T} shift arising from the combination of the Si₁₋ₓGeₓ gate stack and the Si-on-SiGe channel structure. Note that this effect on V_{T} is considered a detractor for n-channel SCI MOSFETs and generally requires that conventional n-channel SCI MOSFETs use higher dopings. As noted earlier, the V_{T} shift reported for p-channel SCI MOSFETs is nearly zero, and is expected to be nearly zero for p-channel Fermi-FETs as well.

Secondly, the strained Si channel can provide a significant enhancement in the mobilities of electrons and holes, although with different behaviors. FIG. 2 graphically illustrates the reported mobility enhancements measured for both electrons and holes. The field value of 1.5 MV/cm illustrates a typical transverse field in an SCI MOSFET in the fully “on” state, with V_{DS}=V_{GS}=V_{DD}. The relative enhancement for electrons is near 80%, with a similar low-field value for holes. One point to note here is that the hole mobility has a much stronger field-dependent rolloff than the electron mobility. At high transverse fields, e.g. above 1 MV/cm, the mobility enhancement nearly vanishes for holes, whereas the relative enhancement is maintained for electrons. The physical mechanism for this does not yet appear to be understood.

Since the Fermi-FET can be, by design, a lower-field/lower-doped structure, several potential benefits relative to the mobility enhancement can be seen by introducing strain into Fermi-FETs. First, for both n and p-channel Fermi-FETs, the lower surface fields in the “on” state can allow the devices to operate towards the regions in FIG. 1 where the absolute magnitude of the mobility is higher. Thus, the use of Fermi-FETs should in general provide a greater degree of enhancement than conventional SCI MOSFETs. More subtly, the p-channel Fermi-FET should provide an even greater relative enhancement than its SCI counterpart, due to the more dramatic p-channel mobility degradation with transverse field. This could lead to more significant overall CMOS performance enhancements than have been reported in the literature. It has been noted in the literature that most biaxially-stressed PMOS devices demonstrate near-zero hole mobility improvement at large vertical fields. See, Thompson et al., “A Logic Nanotechnology Featuring Strained-Silicon”, IEEE Electron Device Letters, Vol. 25, No. 4, April 2004, pp. 191-193. The lower vertical field of a Fermi-FET channel should have a significant effect on the p-channel mobility. Also note that the Fermi-FET generally results in lower doping levels, thus reduced mobility degradation due to ionized impurity scattering may result.

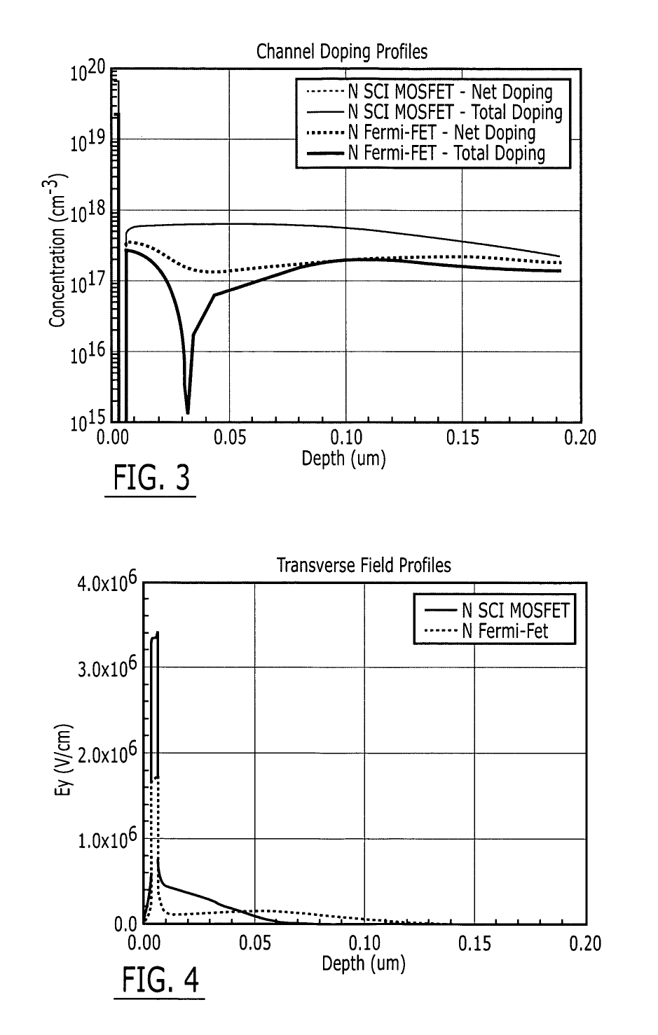

FIG. 3 illustrates an example of channel doping profiles in the center of the channel for typical Fermi-FET and SCI MOSFET channel profiles. These devices are designed at L_{G}=0.18 μm, with identical oxide thicknesses and drain structures. For the case of the SCI MOSFET, the total and net doping curves are nearly identical and are indistinguishable, unlike the Fermi-FET. Note that the total doping curves appear to be the most relevant for discussing mobility degradation due to ionized impurity scattering. Comparing the Fermi-FET total doping to the SCI MOSFET, it can be seen that there is about a factor of two reduction in the total doping near the surface, which can have a significant positive effect on the mobility.

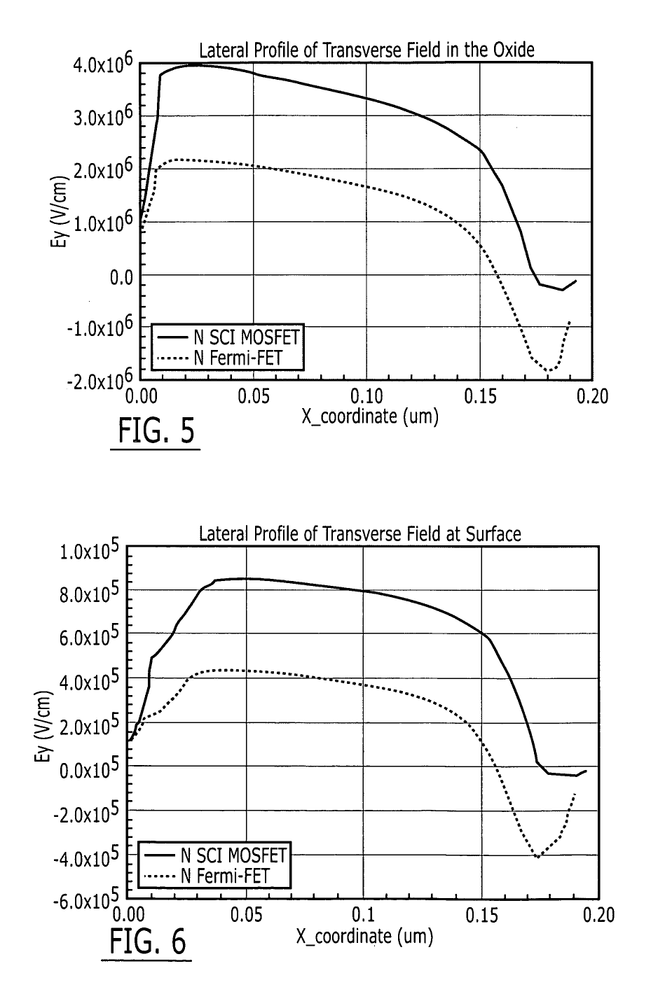

In order to illustrate the differences in field distribution (E_{y}) between conventional SCI MOSFETs and Fermi-FETs, FIGS. 4-6 show comparisons of the transverse electric field distributions. The same two sample SCI MOSFETs and Fermi-FETs are used as for FIG. 3. FIG. 4 is a plot of the transverse (vertical) field profile E_{y} along the same vertical structure cutline as in FIG. 3 (the center of the channel) in the fully “on” state with V_{GS}=V_{DS}=V_{DD}. The reduction in surface field for the Fermi-FET can clearly be seen, as well as the oxide field reduction, which shows in the field spike near Depth=0. FIGS. 5 and 6 show the field distribution in the length (lateral or x) direction or direction of the channel, both in the oxide and at the silicon surface. In the oxide, the shape of the field distribution is virtually identical, but is offset in magnitude. Note however, that the transverse field E_{y} in the silicon is similar at the source and drain ends of the channel, but is significantly lower in magnitude over the rest of the channel for the Fermi-FET. The Fermi-FET fields are seen to be generally about 2× lower than the SCI MOSFET fields up to the point of channel pinchoff. In the pinchoff region, the Fermi-FET field magnitude is higher, but is a negative value. This has a positive effect on device reliability. Often the Fermi-FET field in the pre-pinchoff region of the channel is even lower, which is related to the fact that a Fermi-FET design can have nearly zero field in the oxide and at the silicon surface at threshold (V_{GS}=V_{T}). The reduced field by design can provide for the Fermi-FET's improved mobility and capacitance characteristics.

As noted above, a Fermi-FET can have nearly zero vertical electric field in the oxide and at the silicon surface at threshold. For longer channel devices, where a one-dimensional analysis is valid, a vertical electric field of about 50 kV/cm or less may be provided. For short channel devices, where dopings are increased, oxide thickness is decreased, and other standard techniques may be used to reduce short channel effects, the fields may increase. Thus, for short channel devices, vertical electric fields on the order of about 100-200 kV/cm may be found at the threshold voltage. This is still a factor of about 2-5 below conventional SCI MOSFET devices. It should also be noted that FIGS. 4-6 show fields for devices in the fully “on” state, not at threshold. In a Fermi-FET, there would be little or no “supporting” field at threshold voltage, unlike an SCI MOSFET, which includes a built-in field because of the bulk charge which exists. Stated differently, the Fermi-FET provides a junction-depleted region, whereas an SCI MOSFET provides a gate-depleted region. Since the Fermi-FET provides a junction-depleted region, little or no gate field is needed at the threshold voltage.

From the considerations discussed above, Fermi-FET structures according to embodiments of the invention may be realized from the combination of three architectural features with the following characteristics:

1) Si₁₋ₓGeₓ gate stack (work function shift/reduced poly depletion);
2) Fermi-FET channel structure (low dopings and counter-doped meaning low-fields/low capacitances); and
3) Strained Si-on-SiGe substrate (enhanced mobility, additional V_{T} shift-to compensate for V_{T} from structure in 1 and 2 above).
   Subcombinations of these architectural features also may be provided in other embodiments of the invention. In particular, features 1 and 2, 1 and 3, and 2 and 3 may be provided in other embodiments of the invention.

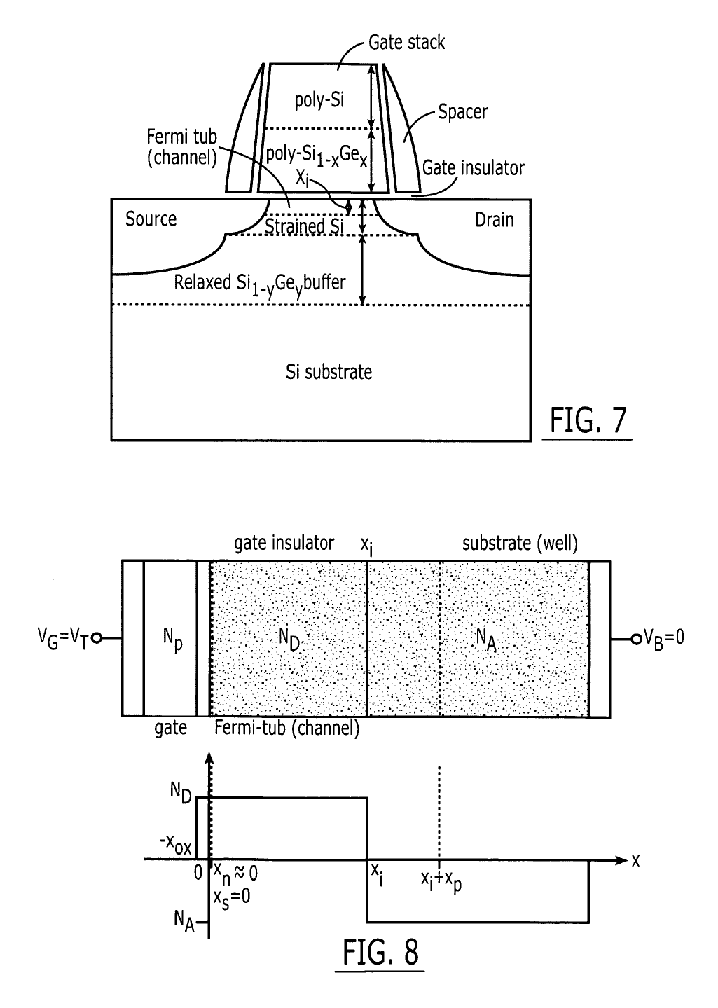

FIG. 7 is a cross-sectional view of a strained Si-on-SiGe Fermi-FET according to exemplary embodiments of the present invention. This is merely a schematic, and the actual extents of the substrate, Si_{1-y}Ge_{y} buffer and strained layer may vary. For an ideally-designed Fermi-FET, the channel dopings are as outlined in FIG. 8. This is an expanded view of the channel region of the device in FIG. 7; basically a one-dimensional picture of the channel profiles. Using the nomenclature defined in FIG. 8, the dopings can satisfy the relationships discussed below to realize ideal Fermi-FET characteristics. Qualitatively, these characteristics include nearly zero field in the gate insulator and at the substrate surface at threshold. For illustrative purposes, an n-channel device is considered, and the analysis follows from a one-dimensional application of Poisson's equation relating charge and potential in the channel.

Referring to FIG. 8, there can be three degrees of freedom or factors responsible for governing the channel potential and field distributions for a counter-doped structure such as the Fermi-FET. They are the Fermi-tub (or channel implant) net doping N_{D}, the underlying substrate (or well) net doping N_{A} and the Fermi-tub junction depth (corresponding to the channel depth) xᵢ as shown in FIG. 8. The depletion region edges are shown as dashed lines at a bias condition of V_{G}=V_{T}. The silicon/oxide interface is defined as xₛ=0, and the substrate (well) bias V_{B}=0. It can be shown by a solution of the 1-D Poisson's equation that the V_{T} of this structure becomes the following,
V_{T}=V_{FB}+V_{bi}

where V_{FB} is the well-known flatband voltage defined by the gate-to-substrate work-function difference Φ_{MS} and miscellaneous charges, which are assumed to be zero for this analysis. For a doped polysilicon gate, the work function difference can be expressed as the difference in Fermi levels between the gate and the substrate (well). V_{bi} is the built-in voltage of the Fermi-tub to substrate junction and is defined as,

$${V}_{bi} = {v}_{th} ln [ \frac{{N}_{A} {N}_{D}}{{n}_{i}^{2}} ] with {v}_{th} = \frac{kT}{q}$$

or the well-known thermal voltage.

Note that the expression for V_{T} has no dependence upon gate oxide thickness xₒₓ. This is indeed the case for an ideal Fermi-FET; the V_{T} is independent of oxide thickness. A corollary feature is that the oxide and surface fields are nearly zero for the case pictured above. In order for this to be true, the three degrees of freedom satisfy the following relationship:

$${x}_{i} = \frac{{N}_{A}}{{N}_{D} + {N}_{A}} \sqrt{\frac{2 {ɛ}_{s}}{q} [ [ \frac{1}{{N}_{A}} + \frac{1}{{N}_{D}} ] ]} ,$$

where xᵢ is the junction depth and is identical to the channel-side extent of the depletion region xₙ. As in FIG. 8, N_{A} is the substrate (well) doping in cm⁻³ and N_{D} is the Fermi-tub (channel) doping in cm⁻³. The other variables are the physical constants for the permittivity of the silicon or other substrate (εₛ) and elementary charge (q=1.6×10⁻¹⁹ coulombs).

With the channel structure built this way, the V_{T} is as defined above, and can be set solely by the gate-to-substrate work function, and the built-in voltage of the channel junction. Note that a unique solution for the condition above generally does not exist. Fixing any two of the factors xᵢ, N_{A} or N_{D} determines the third. Note that the gate work function may also be a function of the poly-Si gate doping. To reduce poly depletion effects and reduce series resistance, a poly-Si or poly-SiGe gate is usually very highly or degenerately doped, so the contribution of the poly-SiGe gate doping to the gate work function is not considered here.

Since this analysis is only 1-D, one might suspect that the behavior for very small geometries may differ, and indeed this may be the case. The influence of a strong drain field can alter the channel potential profile, hence the field distribution. The choices for N_{A}, N_{D} and xᵢ may not arbitrary then and may become constrained by the short-channel effects within the device. As device dimensions are reduced, in accordance with conventional scaling practices, dimensions such as xₒₓ and xᵢ may also need to be reduced in order to properly turn the device off. As the dimensions of xᵢ and xₒₓ shrink, the dopings N_{A} and N_{D} generally must both increase to keep the potential distributions, thus the electric fields within the device generally have the same shape. This is done to make sure the device can adequately turn off, and to increase or maximize the I_{ON}/I_{OFF} ratio. Thus the dopings N_{A} and N_{D} generally cannot be made arbitrarily low for short-channel devices. Note, however that since the Fermi-FET structure, as shown in FIG. 7 provides a built-in field, lighter dopings than a conventional surface inversion MOSFET are generally used for a given xₒₓ and xᵢ. The final effect can be to significantly reduce the operational electric fields within the device, even for short-channel structures, compared with conventional surface inversion MOSFETs.

Note that, since the structure in FIG. 7 can be epitaxially formed, an opportunity exists to create hyper-abrupt channel/well profiles, which the Fermi-FET can greatly benefit from. For example, with a selective epitaxial technique, it could be possible to provide a starting wafer with the Fermi-FET channel conditions pre-defined in the epi. A strained Si layer of about 20 nm could be in-situ doped to completely encompass the Fermi tub. A highly-doped substrate (well) could then be defined fully by the extent of the relaxed Si_{1-y}Ge_{y} buffer layer, allowing a super-steep retrograde or hyper-abrupt channel structure to be formed. The Si substrate could be doped with a steep retrograde implanted well to prevent latchup and soft errors. With modern anneal tools, it would be possible to generate and maintain extremely sharp profiles, which may be generally desirable for very deep submicron device structures. To reiterate, this could use a photolithographically selective epitaxial process, where regions of epitaxial silicon could be grown with different doping levels and types, for example a phosphorous doped epi at a concentration of around 10¹⁷ cm⁻³ for the n-channel device, with a boron-doped epi grown also at a concentration of around 10¹⁷ cm⁻³ based upon conventional mask technology.

It may be possible to define much more symmetrical n and p-channel devices than is possible with implant-only process technology. The reason for this is that the commonly-used implant species diffuse at varying rates due to the physical mechanisms responsible for their diffusion. For example, it is well-known that boron, which could be used for a p-channel Fermi-FET Fermi-tub (channel) doping is a very rapid diffuser in silicon, thus making it difficult to control for defining thin, ultra-sharp profiles. Arsenic, on the other hand, which could be used for n-channel Fermi-FET Fermi-tub (channel) doping is much easier to control since it is a much heavier element and diffuses more slowly. If boron and arsenic were used for the p-channel and n-channel Fermi-FETs, respectively, the resulting channel profiles could be quite different, resulting in asymmetrical electrical performance. The use of the epitaxial technique described above could allow p-channel and n-channel Fermi-FETs with nearly identical extents and shapes, resulting in much more symmetrical electrical behavior.

Note that it has been recognized in Fossum et al., cited above, that the use of p+ poly-SiGe gate stacks can reduce gate depletion and boron penetration effects on conventional p-channel MOSFETs using a Si-on-SiGe channel structure. However, this discussion is focused on the n-channel device, and demonstrates how the combination of the p+ poly-SiGe gate stack and the Fermi-FET channel can provide further enhancements for the n-channel device, as well as the p-channel device.

### SUMMARY

The following equations may be used to design a Fermi-FET according to embodiments of the present invention.

The theoretical Fermi-FET channel expressions for the V_{T} and the relationship among the dopings N_{A}, N_{D} and xᵢ are as follows:
V_{T}=V_{FB}+V_{bi}
where

$${V}_{FB} = {Φ}_{MS} and {V}_{bi} = {v}_{th} ln ( \frac{{N}_{A} {N}_{D}}{{n}_{i}^{2}} ) with {v}_{th} = \frac{kT}{q}$$

(the thermal voltage).

The dopings N_{A} and N_{D} can meet the following criterion:

$${x}_{i} = \frac{{N}_{A}}{{N}_{D} + {N}_{A}} \sqrt{\frac{2 ɛ}{q} [ [ \frac{1}{{N}_{A}} + \frac{1}{{N}_{D}} ] ]}$$

where xᵢ is the depth of the N_{D}-side of the Fermi-tub (channel) junction as shown in FIG. 8. Including the effects of the poly-Si₁₋ₓGeₓ gate and the Si-on-SiGe substrate, the net Fermi-FET threshold voltage V_{TN} becomes:
V_{TN}=Φ_{MS}+V_{bi}−ΔV_{TG}−ΔV_{TSUB}
where ΔV_{TG} is the shift in V_{T} due to the poly-Si₁₋ₓGeₓ gate structure. Values for the Ge content x in the poly-Si₁₋ₓGeₓ gate could be determined from data points as in FIG. 1 to set Φ_{MS} or can come from experimental data. The term ΔV_{TSUB} is the additional shift in V_{T} due to the Si_{1-y}Ge_{y} substrate and can be defined empirically as:
ΔV_{TSUB}=E_{g(Si)}−E_{g(SilSiGe)}=0.4y
where y is the Ge content in the relaxed Si_{1-y}Ge_{y} buffer layer.

### EXAMPLE

The following example is merely illustrative and shall not be construed as limiting the present invention. A long-channel device design is shown below. As discussed above, due to short-channel effects such as charge sharing, the final device threshold V_{TN} may be somewhat lower than the long-channel value. The exact amount of this shift is generally extremely difficult to determine analytically and is generally dependent upon a large number of factors not considered in this discussion. The following expressions are used to determine the values in the design table:

$${V}_{TN} = {Φ}_{MS} + {V}_{bi} - Δ {V}_{TG} - Δ {V}_{TSUB}$$

$${Φ}_{MS} = {ϕ}_{Gp} - {ϕ}_{SUBp} where$$

$${ϕ}_{Gp} = \frac{- kT}{q} ln ( \frac{{N}_{Apoly}}{{n}_{i}} ) where {N}_{Apoly} is the poly gate doping$$

$${ϕ}_{SUBp} = \frac{- kT}{q} ln ( \frac{{N}_{A}}{{n}_{i}} )$$

$${V}_{bi} = \frac{kT}{q} ln ( \frac{{N}_{A} {N}_{D}}{{n}_{i}^{2}} )$$

$$Δ {V}_{TSUB} = {E}_{g ( Si )} - {E}_{g ( SilSiGe )} = 0.4 y$$

$$Δ {V}_{TG} from experimental data assumed to be 0.4 V$$

| Parameter | Description | Value |
|---|---|---|
| N_{A} | Substrate doping | 10¹⁸ cm⁻³ |
| N_{D} | Fermi-tub doping | 10¹⁷ cm⁻³ |
| xᵢ | Fermi-tub depth | 0.109 μm |
| x | Gate Ge content | 70.00% |
| y | Substrate Ge content | 40.00% |
| ΔV_{TSUB} | V_{T} shift due to Si-on-SiGe substrate | 0.16 V |
| ΔV_{TG} | V_{T} shift due to poly-Siₗ₋ₓGeₓ gate stack | 0.40 V |
| V_{TN} | Final device V_{T} | 0.398 V |

### CONCLUSIONS

It has been shown herein that the facts that higher dopings generally are used for both n and p-channel MOSFET devices, and that the p-channel devices do not enjoy the same relative enhancement as the n-channel devices, may combine to significantly reduce the actual performance of strained Si-on-SiGe circuits. In addition, due to the generally higher dopings, and the bandgap reduction, junction capacitances in the strain layer generally are higher, further reducing performance. In practice, performance gains of no more than 20-25% may be seen.

In contrast, the fact that lighter dopings are typically used in Fermi-FETs, and the transverse surface fields are typically much lower than in SCI devices can combine to allow the Fermi-FET to enjoy significantly more benefit from strained-Si mobility enhancement, as well as two more potential advantages: a greater degree of relative hole mobility enhancement for the p-channel Fermi-FETs, and the capability to use SiGe gate stack technology for the n-channel Fermi-FET due to the V_{T} shift. Concerning the previously discussed potential disadvantages, since the Fermi-FET device design usually uses lower dopings, the impact on leakage current and capacitance can be reduced as well, compared with conventional SCI MOSFETs.

The present invention has been described herein with reference to the accompanying drawings, in which exemplary embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Moreover, each embodiment described and illustrated herein includes its complementary conductivity type embodiment as well. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items and may be abbreviated as “/”.

Embodiments of the invention were described herein with reference to illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. All publications, patent applications, patents, and other references mentioned herein are incorporated by reference in their entirety.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A field effect transistor comprising:
a strained silicon channel in a substrate;
source/drain regions in the substrate at opposite ends of the strained silicon channel;
a gate insulating layer on the strained silicon channel, wherein doping of the strained silicon channel, doping of the substrate and/or a depth of the strained silicon channel are configured to produce nearly zero vertical electric field in the gate insulating layer and in the strained silicon channel adjacent thereto at a threshold voltage of the field effect transistor; and
a gate on the gate insulating layer that is configured to provide a gate work function that is close to a mid-bandgap of silicon.

2. A field effect transistor according to claim 1 further comprising:
a relaxed silicon-germanium buffer layer between the substrate and the strained silicon channel that is configured to apply strain to the strained silicon channel.

3. A field effect transistor according to claim 1 wherein the gate comprises polysilicon-germanium.

4. A field effect transistor according to claim 3 wherein the gate further comprises a polysilicon layer on the polysilicon-germanium remote from the gate insulating layer.

5. A field effect transistor according to claim 1 wherein the gate is configured to provide a gate work function that is within about 0.3 eV of the mid-bandgap of silicon.

6. A field effect transistor according to claim 1 wherein the gate is configured to provide a gate work function of about 4.7 eV.

7. A field effect transistor according to claim 1 wherein the doping of the channel, the doping of the substrate and/or the depth of the channel are selected according to:
$${x}_{i} = \frac{{N}_{A}}{{N}_{D} + {N}_{A}} \sqrt{\frac{2 {ɛ}_{s}}{q} [ [ \frac{1}{{N}_{A}} + \frac{1}{{N}_{D}} ] ]}$$
wherein xᵢ is the depth of the channel, N_{A} is the substrate doping N_{D} is the channel doping, εₛ is the permittivity of silicon and q is the elementary charge.

8. A field effect transistor comprising:
a strained silicon channel in a substrate;
source/drain regions in the substrate at opposite ends of the strained silicon channel;
a gate insulating layer on the strained silicon channel, wherein doping of the strained silicon channel, doping of the substrate and/or a depth of the strained silicon channel are configured to produce nearly zero vertical electric field in the gate insulating layer and in the strained silicon channel adjacent thereto at a threshold voltage of the field effect transistor; and
a gate on the gate insulating layer.

9. A field effect transistor according to claim 8 further comprising:
a relaxed silicon-germanium buffer layer between the substrate and the strained silicon channel that is configured to apply strain to the strained silicon channel.

10. A field effect transistor according to claim 8 wherein the doping of the channel, the doping of the substrate and/or the depth of the channel are selected according to:
$${x}_{i} = \frac{{N}_{A}}{{N}_{D} + {N}_{A}} \sqrt{\frac{2 {ɛ}_{s}}{q} [ [ \frac{1}{{N}_{A}} + \frac{1}{{N}_{D}} ] ]}$$
wherein xᵢ is the depth of the channel, N_{A} is the substrate doping N_{D} is the channel doping, εₛ is the permittivity of silicon and q is the elementary charge.

11. A field effect transistor comprising:
a channel in a substrate;
source/drain regions in the substrate at opposite ends of the channel;
a gate insulating layer on the channel, wherein doping of the channel, doping of the substrate and/or a depth of the channel are configured to produce nearly zero vertical electric field in the gate insulating layer and in the channel adjacent thereto at a threshold voltage of the field effect transistor; and
a gate on the gate insulating layer that is configured to provide a gate work function that is close to a mid-bandgap of silicon.

12. A field effect transistor according to claim 11 wherein the gate comprises polysilicon-germanium.

13. A field effect transistor according to claim 12 wherein the gate further comprises a polysilicon layer on the polysilicon-germanium remote from the gate insulating layer.

14. A field effect transistor according to claim 11 wherein the gate is configured to provide a gate work function that is within about 0.3 eV of the mid-bandgap of silicon.

15. A field effect transistor according to claim 11 wherein the gate is configured to provide a gate work function of about 4.7 eV.

16. A field effect transistor according to claim 1 wherein the doping of the channel, the doping of the substrate and/or the depth of the channel are selected according to:
$${x}_{i} = \frac{{N}_{A}}{{N}_{D} + {N}_{A}} \sqrt{\frac{2 {ɛ}_{s}}{q} [ [ \frac{1}{{N}_{A}} + \frac{1}{{N}_{D}} ] ]}$$
wherein xᵢ is the depth of the channel, N_{A} is the substrate doping N_{D} is the channel doping, εₛ is the permittivity of silicon and q is the elementary charge.

17. A field effect transistor comprising:
a strained silicon channel in a substrate;
source/drain regions in the substrate at opposite ends of the strained silicon channel;
a gate insulating layer on the strained silicon channel; and
a gate on the gate insulating layer that is configured to provide a gate work function that is close to a mid-bandgap of silicon.

18. A field effect transistor according to claim 17 further comprising:
a relaxed silicon-germanium buffer layer between the substrate and the strained silicon channel that is configured to apply strain to the strained silicon channel.

19. A field effect transistor according to claim 7 wherein the gate comprises polysilicon-germanium.

20. A field effect transistor according to claim 19 wherein the gate further comprises a polysilicon layer on the polysilicon-germanium remote from the gate insulating layer.

21. A field effect transistor according to claim 17 wherein the gate is configured to provide a gate work function that is within about 0.3 eV of the mid-bandgap of silicon.

22. A field effect transistor according to claim 17 wherein the gate is configured to provide a gate work function of about 4.7 eV.

23. A method of fabricating a field effect transistor comprising:
epitaxially growing a relaxed silicon-germanium buffer layer on a silicon substrate;
epitaxially growing a strained silicon channel on the relaxed silicon-germanium buffer layer;
forming source/drain regions in the substrate at opposite ends of the strained silicon channel;
forming a gate insulating layer on the strained silicon channel, wherein doping of the strained silicon channel, doping of the substrate and/or a depth of the strained silicon channel are configured to produce nearly zero vertical electric field in the gate insulating layer and in the strained silicon channel adjacent thereto at a threshold voltage of the field effect transistor; and
forming a gate on the gate insulating layer that is configured to provide a gate work function that is close to a mid-bandgap of silicon.

24. A method according to claim 23 wherein forming source/drain regions comprises selectively epitaxially growing the source/drain regions during the epitaxially growing of the relaxed silicon-germanium buffer layer and/or the epitaxially growing of the strained silicon channel.
